(19) United States
(12) Patent Application Publication
(10) Pub. No.: US 2025/0218737 A1
(43) Pub. Date: Jul. 3, 2025

(54) PLASMA SOURCE COOLING SYSTEM

(71) Applicants: Beijing E-Town Semiconductor Technology Co., Ltd., Beijing (CN); Mattson Technology, Inc., Fremont, CA (US)

(72) Inventors: Songjae Lee, San Jose, CA (US); Xiaotong Zhang, San Jose, CA (US)

(21) Appl. No.: 18/988,207

(22) Filed: Dec. 19, 2024

Related U.S. Application Data
(60) Provisional application No. 63/616,161, filed on Dec. 29, 2023.

(51) Int. Cl. H01J 37/32

(52) U.S. Cl. CPC H01J 37/32522; H01J 37/321; H01J 37/32651; H01J 2237/002

(57) ABSTRACT

Cooling systems and methods for plasma sources used in semiconductor fabrication are provided. In one example, the plasma source includes an induction coil about a dielectric tube. The plasma processing apparatus further includes a Faraday shield located between the induction coil and the dielectric tube. The Faraday shield includes a plurality of Faraday shield slits. The plasma processing apparatus further includes a plasma source cooling system including a manifold. The manifold includes a plurality of nozzles, each nozzle configured to supply cooling fluid onto a surface of the dielectric tube through one of the Faraday shield slits of the plurality of Faraday shield slits.

### PRIORITY CLAIM

The present application is based on and claims priority to U.S. Provisional Application 63/616,161 having a filing date of Dec. 29, 2023, which is incorporated by reference herein.

### FIELD

The present disclosure relates generally to apparatus, systems, and methods for plasma processing of a workpiece.

### BACKGROUND

Plasma processing is widely used in the semiconductor industry for deposition, etching, resist removal, and related processing of semiconductor wafers and other substrates. Plasma sources (e.g., microwave, ECR, inductive coupling, etc.) are often used in plasma processing to produce high density plasma and reactive species for processing substrates. In plasma dry strip processes, neutral species (e.g., radicals) from a plasma generated in a remote plasma chamber pass through a separation grid into a processing chamber to treat a workpiece, such as a semiconductor wafer. In plasma etch processes, radicals, ions, and other species generated in a plasma directly exposed to the workpiece can be used to etch and/or remove a material on a workpiece.

### SUMMARY

Aspects and advantages of embodiments of the present disclosure will be set forth in part in the following description, or may be learned from the description, or may be learned through practice of the embodiments.

One example aspect of the present disclosure is directed to a plasma processing apparatus including a plasma source. The plasma source includes an induction coil about a dielectric tube. The plasma processing apparatus further includes a Faraday shield located between the induction coil and the dielectric tube. The Faraday shield includes a plurality of Faraday shield slits. The plasma processing apparatus further includes a plasma source cooling system including a manifold. The manifold includes a plurality of nozzles, each nozzle configured to supply cooling fluid onto a surface of the dielectric tube through one of the Faraday shield slits of the plurality of Faraday shield slits.

Another example aspect of the present disclosure is directed to a plasma source cooling system including a plasma chamber cage configured to house the plasma source and a Faraday shield, the Faraday shield located between an induction coil and a dielectric tube of the plasma source, the Faraday shield comprising a plurality of Faraday shield slits. The plasma source cooling system further includes a manifold located within a lower portion of the plasma chamber cage, the manifold comprising a plurality of nozzles, each nozzle configured to supply cooling fluid to the plasma source through one of the Faraday shield slits of the plurality of Faraday shield slits.

Another example aspect of the present disclosure is directed to a method for cooling a plasma source. The method includes generating, by a plasma source, a plasma within a plasma chamber, the plasma source comprising an induction coil about a plasma chamber, wherein a Faraday shield is located between the induction coil and the plasma chamber. The method also includes injecting, by a plurality of nozzles of a manifold, cooling fluid to a surface of the plasma chamber through a plurality of slits in the Faraday shield.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example plasma processing apparatus according to example embodiments of the present disclosure;

FIG. 2 depicts an example Faraday shield according to example embodiments of the present disclosure;

FIG. 3 depicts an example plasma source cooling system according to example embodiments of the present disclosure;

FIG. 4 depicts a plasma processing apparatus according to example embodiments of the present disclosure;

FIG. 5A depicts a cross-sectional illustration of the flow path of cooling fluid provided to the plasma source by plasma source cooling systems according to example embodiments of the present disclosure;

FIG. 5B depicts a cross-sectional illustration of the flow path of cooling fluid provided to the plasma source by plasma source cooling systems according to example embodiments of the present disclosure;

FIG. 5C depicts a cross-sectional illustration of the flow path of cooling fluid provided to the plasma source by plasma source cooling systems according to example embodiments of the present disclosure; and

FIG. 6 depicts a flowchart of an example method for cooling a plasma source according to example embodiments of the present disclosure.

### DETAILED DESCRIPTION

Example aspects of the present disclosure are directed to a cooling system for a plasma source that provides for heat removal from the plasma source. Plasma sources may suffer from problems relating to overheating. For instance, plasma sources can include a dielectric chamber or tube within which the plasma is contained. In high power applications, the energy transmitted through the dielectric material to energize the plasma heats the dielectric material and causes material degradation, in some cases leading to failure or breach (e.g., cracking of ceramic dielectric chamber). The problem may be compounded for inductively coupled plasma sources, which can include a high-power induction coil encircling the dielectric tube. In such configurations, the dielectric tube is exposed to extreme heat. Thus, it may be desirable to cool the surface of the dielectric tube using a cooling fluid.

In some cases, a Faraday shield may be used to reduce capacitive coupling between the induction coil and the plasma within the dielectric chamber. However, the use of the Faraday shield may introduce several challenges in applying cooling fluid to the dielectric tube. For example, the surface area of the dielectric tube that can be contacted by the cooling fluid is greatly reduced by the use of the Faraday shield. Further, the flow path of the cooling fluid may be impeded by the Faraday shield and directed away from the dielectric tube.

Aspects of the present disclosure provide a plasma source cooling system capable of guiding flow of cooling fluid (e.g., cooling gas, such as air) directly to the surface of the dielectric tube of a plasma source through slits in a Faraday shield at a high flow rate. In some embodiments, the cooling system may include a manifold with one or more nozzles. Each nozzle is positioned on the manifold such that cooling fluid may be injected through a slit in the Faraday shield to the surface of the dielectric tube.

In some embodiments, a plasma processing apparatus according to aspects of the present disclosure can include a plasma source including an induction coil surrounding a dielectric tube. The apparatus may further include a Faraday shield (e.g., electromagnetic shield) located between the induction coil and the dielectric tube to reduce capacitive coupling between the induction coil and the plasma. The Faraday shield includes a plurality of Faraday shield slits (e.g., eight Faraday shield slits) exposing the surface of the dielectric tube. Cooling fluid (e.g., cooling gas, such as air) may be injected through each of the Faraday shield slits to the surface of the dielectric tube via a plurality of nozzles. The plurality of nozzles may be attached to or form a part of a manifold (e.g., ring-shaped manifold).

Aspects of the present disclosure provide a number of technical effects and benefits. For instance, examples of the present disclosure provide for a plasma source cooling system that can quickly and effectively cool the dielectric tube of a plasma source, which greatly reduces the likelihood of system failure or chamber breach (e.g., cracking of the dielectric tube). Further, examples of the present disclosure may provide for a plasma source cooling system that may stabilize the temperature across the dielectric tube and reduce the temperature of the Faraday shield.

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor workpiece or other suitable workpiece. In addition, the use of the term “about” in conjunction with a numerical value is intended to refer to within ten percent (10%) of the stated numerical value. A “pedestal” refers to any structure that can be used to support a workpiece. A “remote plasma” refers to a plasma generated remotely from a workpiece, such as in a plasma chamber separated from a workpiece by a separation grid. A “direct plasma” refers to a plasma that is directly exposed to a workpiece, such as a plasma generated in a processing chamber having a pedestal operable to support the workpiece.

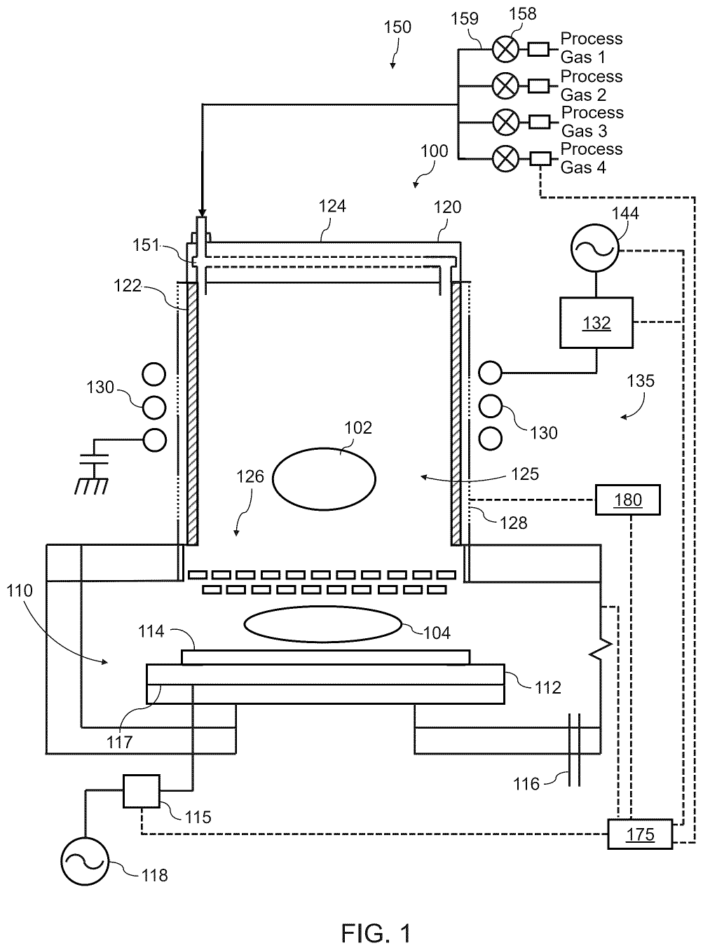

FIG. 1 depicts an example plasma processing apparatus 100 that can be used to implement processes, components, and systems according to example embodiments of the present disclosure. The plasma processing apparatus 100 may include a processing chamber 110. Processing chamber 110 may include a workpiece support 112 or pedestal operable to hold a workpiece 114 to be processed or treated, such as a semiconductor wafer.

The plasma processing apparatus 100 may further include a plasma source 135 configured to generate a plasma used to treat the workpiece 114. Plasma source 135 may include a plasma chamber 120 such as a remote plasma chamber that is separated from the processing chamber 110 by a separation grid 126. The plasma chamber 120 includes a dielectric tube 122 (e.g., having dielectric side wall) and a ceiling 124. The dielectric tube 122, ceiling 124, and separation grid 126 may define a plasma generation region 125 (e.g., plasma chamber interior). Dielectric tube 122 can be a dielectric material, such as quartz and/or alumina. In some embodiments, dielectric tube 122 is a ceramic material. The dielectric tube 122 can include an outer surface that does not face the plasma generation region 125. The plasma source 135 further includes a source coil assembly such as an induction coil 130 disposed around the dielectric tube 122 about the plasma chamber 120. The induction coil 130 may be coupled to an RF power generator 144 through a suitable matching network 132.

In some embodiments, the plasma processing apparatus 100 can include a controller 175. Controller 175 may control various components of the plasma processing apparatus 100 to direct processing of workpiece 114. For example, controller 175 can be used to control power sources (e.g., DC power source, AC power source, and/or RF power source) connected to the induction coil 130. Additionally and/or alternatively, controller 175 can be in communication (e.g., wireless communication) with a temperature measurement system 180 configured to measure the temperature of the plasma chamber 120 and/or dielectric tube 122.

In some embodiments, gas supply 150 may provide (e.g., deliver) process gas to gas distribution channel 151 of the plasma chamber 120 from gas feed lines 159. Example process gases may include oxygen-containing gases (e.g. O₂, O₃, N₂O, H₂O), hydrogen-containing gases (e.g., H₂), nitrogen-containing gas (e.g. N₂, NH₃, N₂O), fluorine-containing gases (e.g. CF₄, C₂F₄, CHF₃, CH₂F₂, CH₃F, SF₆, NF₃), hydrocarbon-containing gases (e.g. CH₄), or combinations thereof. Other feed gas lines containing other gases can be added as needed. In some embodiments, the process gas can be mixed with an inert gas that can be called a “carrier” gas, such as He, Ar, Ne, Xe, or N₂. A control valve 158 can be used to control a flow rate of each feed gas line to flow a process gas into the plasma chamber 120.

In some embodiments, plasma processing apparatus 100 may generate a first plasma 102 (e.g., a remote plasma) in the plasma chamber 120 and a second plasma 104 (e.g., a direct plasma) in the processing chamber 110. More particularly, plasma processing apparatus 100 may include a bias source having a bias electrode 117 in the workpiece support 112. The bias electrode 117 can be coupled to an RF power generator 118 via a suitable matching network 115. When the bias electrode 117 is energized with RF energy, a second plasma 104 can be generated from a mixture in the processing chamber 110 for direct exposure to the workpiece 114. The processing chamber 110 can include a gas exhaust port 116 for evacuating a gas from the processing chamber 110.

In this example illustration, a plasma 102 is generated by the plasma source 135 within the plasma chamber 120 at the plasma generation region 125. Desired species are then channeled from the plasma chamber 120 to the surface of workpiece 114 through the separation grid assembly 126.

The plasma processing apparatus 100 further includes a Faraday shield 128 (e.g., a grounded Faraday shield) located between the induction coil 130 and the dielectric tube 122 of the plasma chamber 120, for example, to reduce capacitive coupling between the induction coil 130 and the plasma 102 within the plasma chamber 120. In some embodiments, Faraday shield 128 may be spaced apart from the dielectric tube 122.

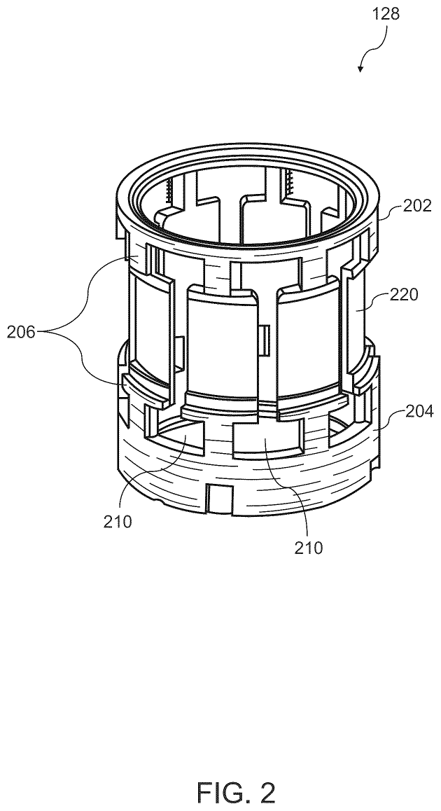

In reference to FIG. 2, Faraday shield 128 may include a top annular portion 202 and a bottom annular portion 204 which may encircle the plasma chamber 120. A tubular side wall 206 is coupled between the top annular portion 202 and the bottom annular portion 204 about the dielectric tube. The tubular side wall 206 includes multiple slits 210 (e.g., air gaps), exposing the dielectric tube 122 of the plasma chamber 120. The slits 210 depicted in FIG. 2 are “dog bone” shaped slits in that they have two wider portions connected by a narrower portion. However, in some embodiments, the slits 210 may have other shapes. In some embodiments, tubular side wall 206 may include one or more electrically conductive pads 220. In some embodiments, multiple slits 210 (e.g., air gaps) exist within the tubular side wall 206, such as between electrically conductive pads 220, exposing the exterior surface of dielectric tube 122 of the plasma chamber 120.

The plasma processing apparatus 100 further includes a plasma source cooling system, such as that described herein, configured to cool the plasma source 135 by suppling cooling fluid (e.g., cooling gas, such as air) to the external surface of the dielectric tube 122 through multiple slits in the Faraday shield 128.

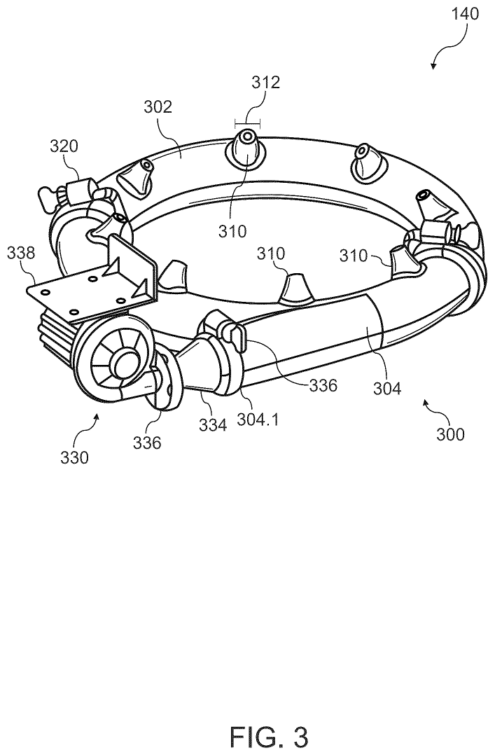

FIG. 3 depicts a plasma source cooling system 140 according to example embodiments of the present disclosure. In some embodiments, the plasma source cooling system 140 can be used in a plasma processing apparatus such as that shown in FIG. 1 to cool the plasma source.

Plasma source cooling system 140 includes a manifold 300. In some embodiments, manifold 300 may be a ring-shaped manifold. The manifold 300 includes multiple nozzles 310 extending from the manifold 300. Each nozzle 310 may be positioned around the manifold 300 at an equal radial distance from one another. However, in some embodiments, the nozzles 310 may be irregularly spaced. Each nozzle 310 of the manifold 300 may have an opening diameter 312 in a range of about 3 mm to about 12 mm, such as about 6.35 mm. Each nozzle 310 may inject cooling fluid (e.g., cooling gas, such as air) at a rate of about 8 m/s. In some embodiments, the manifold 300 may include eight nozzles, such that the plurality of nozzles may inject cooling gas (e.g., air, compressed air) out of the nozzles 310 at a combined rate greater than about 50 m/s, such as about 60 m/s. In some embodiments, the cooling fluid may be air (e.g., compressed air) and nozzles 310 may be shaped such that a high-velocity air-jet is projected to the dielectric tube 122.

In some embodiments, a blower 330 is used to supply cooling fluid such as cooling gas (e.g., air, such as ambient air) to the manifold 300. The blower 330 may be attached to the manifold 300 at inlet 304.1 using, for example, a blower adaptor 334 and/or one or more blower clamps 336. This allows for the blower 330 to be serviced or replaced without disassembling other components of the system. In some embodiments, a compressed air source may provide compressed air to the manifold and/or individually to each of the plurality of nozzles.

In some embodiments, the manifold 300 may include two manifold splits 302, 304. A first manifold split 304 may include an inlet 304.1 to be attached to blower 330. The first manifold split 304 and the second manifold split 302 may be attached at two ends using, for example, clamps 320. The blower 330 may be attached to the first manifold split 304 using, for example, a blower adaptor 334 and/or one or more blower clamps 336. The use of the first and second manifold splits 302, 304 can allow for more efficient assembly of the plasma source cooling system 140 as well as replacement of damaged components.

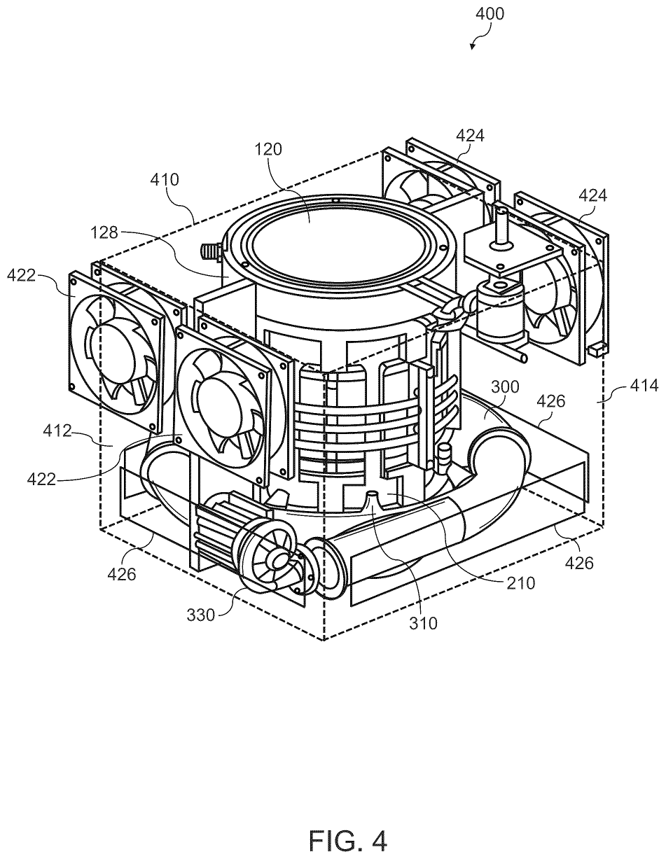

FIG. 4 illustrates a plasma processing apparatus 400 according to example embodiments of the present disclosure. In some embodiments, the plasma processing apparatus 400 can include one or more plasma processing apparatus such as that shown in FIG. 1. The plasma processing apparatus 400 includes various components discussed previously. Except where otherwise indicated, like reference numerals are used to represent like components previously disclosed.

The plasma processing apparatus 400 provides for the cooling of the plasma source 135 by applying cooling fluid (e.g., cooling gas, such as air) to the dielectric tube 122 of the plasma chamber 120 (FIG. 1).

The plasma processing apparatus 400 may include a plasma chamber cage 410 and manifold 300. In some embodiments, plasma processing apparatus 400 may further include Faraday shield 128. Plasma chamber cage 410 is configured to house the plasma chamber 120, Faraday shield 128, and manifold 300. In some embodiments, the plasma chamber cage 410 is sealed to provide for more efficient flow control of cooling fluid.

The manifold 300 may be a ring-shaped manifold and is configured to inject cooling fluid such as cooling gas (e.g., air, compressed air) through slits 210 in the Faraday shield 128 to the exterior surface of the plasma chamber 120 (e.g., dielectric tube 122 (FIG. 1)). Each nozzle 310 may inject cooling fluid (e.g., cooling gas, such as air) at a speed of about 8 m/s. The manifold 300 may include multiple nozzles 310 positioned such that the cooling fluid (e.g., cooling gas, air, compressed air) is projected through the slits 210 at a combined speed such as speed greater than about 50 m/s, such as about 60 m/s. The manifold 300 may include a number of nozzles 310 that corresponds to a number of slits 210 in the Faraday shield 128 with each nozzle 310 corresponding to a single slit 210. For example, Faraday shield 128 may include eight slits 210 and manifold 300 may include eight nozzles 310.

Plasma processing apparatus 400 may further include a blower 330 to supply cooling fluid such as cooling gas (e.g., air, compressed air) into the plasma chamber cage 410 via the manifold 300. In some embodiments, the blower 330 may be located outside of the plasma chamber cage 410 and blower mounting bracket 338 shown in FIG. 3 may be used to mount the blower to an external surface of a side wall 412 of the plasma chamber cage 410. In some embodiments, the blower may be located within the plasma chamber cage 410.

In some embodiments, plasma processing apparatus 400 further includes one or more fans 422, 424 configured to extract the cooling fluid from the plasma chamber cage 410. The one or more fans 422, 424 may be mounted onto an exterior surface of the plasma chamber cage 410, such as an upper portion of the plasma chamber cage 410. For example, the one or more fans 422, 444 may be positioned such that the cooling fluid is extracted at an upper portion of the plasma chamber cage 410 to provide cooling fluid flow (e.g., airflow) around the plasma source 135. In some embodiments, fans 422 may be mounted on an external surface of a first side wall 412 of the plasma chamber cage 410, while fans 424 may be mounted opposite fans 422 on an external surface of a second side wall 414 of the plasma chamber cage 410. In some embodiments, fans 422, 424 may include a shield (e.g., cover) to provide protection against UV energy or RF energy.

In some embodiments, fans 422, 424 may extract cooling fluid from the plasma chamber cage 410 at a rate greater than blower 330 can supply cooling fluid into the plasma chamber cage. Accordingly, plasma processing apparatus 400 may include one or more fluid inlets 426 configured to supply additional cooling fluid (e.g., air, compressed air). The one or more fluid inlets 426 may be located on each side wall at a lower portion of the plasma chamber cage 410. Cooling fluid injected to the plasma chamber cage 410 by the one or more fluid inlets 426 form a vertical flow path such that cooling fluid is directed to the manifold 300, nozzles 310, and Faraday shield 128. As such, fluid inlets 426 may provide cooling fluid to components not directly in the flow path of cooling fluid from nozzles 310 of the manifold 300. In some embodiments, fluid inlets 426 may include a shield (e.g., cover) to provide protection against UV energy or RF energy.

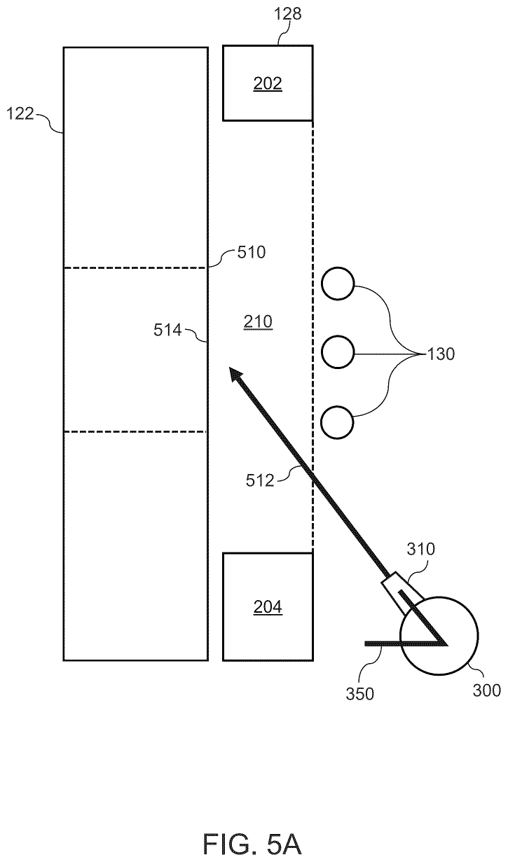

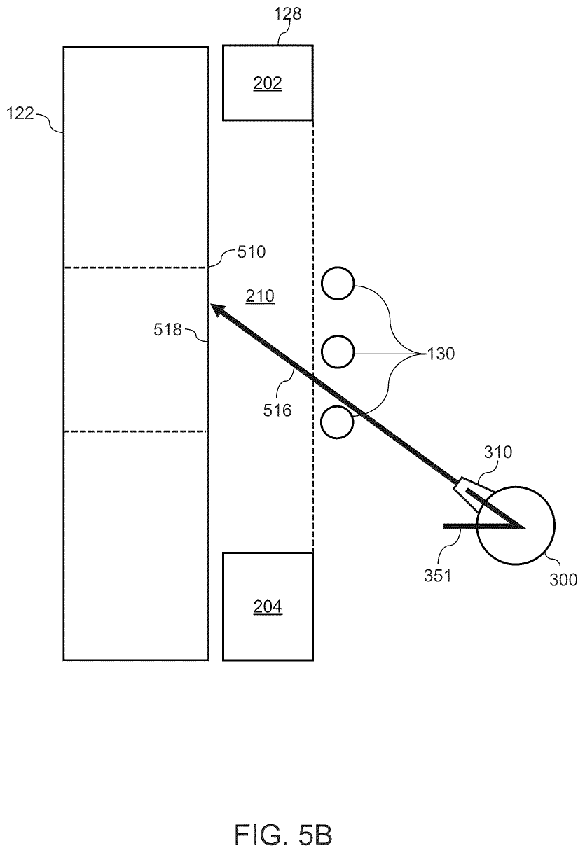

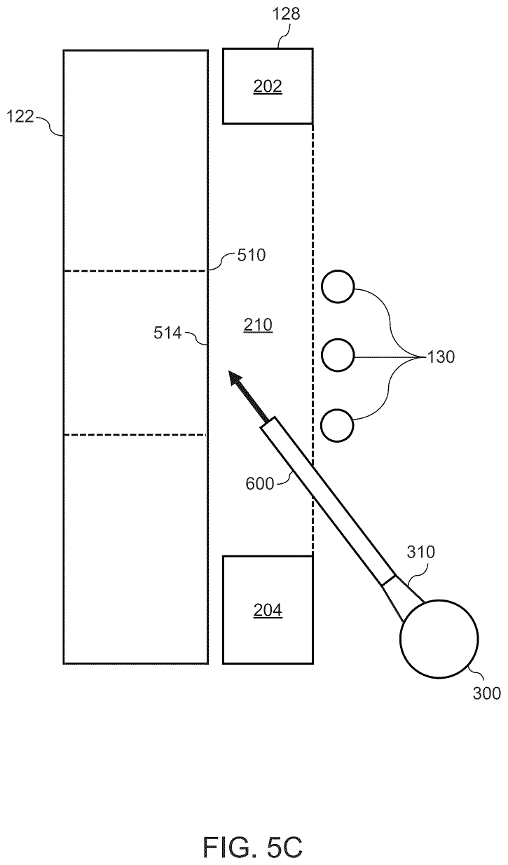

FIGS. 5A-5C provide cross-sectional illustrations of the flow path of cooling fluid provided to the plasma source by plasma source cooling systems according to example embodiments of the present disclosure. One of ordinary skill in the art will understand that any of the fluid flow paths described with reference to FIGS. 5A-5C may be used in any embodiment of the plasma source cooling system described herein.

Referring now to FIG. 5A, manifold 300 supplies cooling fluid to nozzle 310. Nozzle 310 is configured to inject the cooling fluid through Faraday shield slit 210 to the external surface 510 of dielectric tube 122. In some embodiments, nozzle 310 may be configured to supply cooling fluid to the dielectric tube 122. In some embodiments, nozzle 310 is configured to supply the cooling fluid to the dielectric tube 122 at a position 514 defined by induction coil 130. Specifically, the cooling fluid may be provided onto the dielectric tube 122 at a position 514 located on the dielectric tube 122 at a horizontal plane that overlaps induction coil 130. Further, the cooling liquid may enter Faraday shield slit 210 at a position not defined by induction coil 130, such as a at a position 512 below induction coil 130. Providing the cooling fluid directly to position 514 may be beneficial as the dielectric tube may experience even greater temperatures at position 514 due to its proximity to induction coil 130.

Nozzle 310 may extend from the manifold 300 at an angle 350 that provides for the flow of the cooling fluid (e.g., cooling gas, such as air) to provide the cooling fluid to the surface of the dielectric tube 122 at a position 514 defined by induction coil 130. Further, nozzle 310 may extend from the manifold 300 at an angle 350 that provides the cooling fluid to the dielectric tube 122 at a position 514 defined by induction coil 130 and flow vertically upwards along the surface of the dielectric tube 122 towards the top annular portion 202 of the Faraday shield 128.

Manifold 300 may be located about a lower portion of the Faraday shield 128, such as, at a position below induction coil 130. In some embodiments, manifold 300 may be located about Faraday shield 128 at a position horizontally corresponding to the bottom annular portion 204 of Faraday shield 128.

Referring now to FIG. 5B, manifold 300 supplies cooling fluid to nozzle 310. Nozzle 310 is configured to inject the cooling fluid through Faraday shield slit 210 to the external surface 510 of dielectric tube 122. In some embodiments, nozzle 310 may be configured to supply cooling fluid to the dielectric tube 122 at a position 518 defined by induction coil 130. Specifically, the cooling fluid may contact the dielectric tube 122 at a position 518 located on the dielectric tube 122 at a horizontal plane that overlaps induction coil 130. Further, the cooling liquid may enter Faraday shield slit 210 at a position also defined by induction coil 130, such as at position 516 located between the coils of induction coil 130.

FIG. 5C shows tube 600 attached to (e.g., coupled to) the nozzle 310. Specifically, tube 600 may be coupled to nozzle 310 extending from the manifold 300. The tube 600 may provide further guidance to the flow of fluid through the Faraday shield slit 210 to the surface of the dielectric tube 122 to cool the exterior surface of plasma chamber 120 (e.g., dielectric tube 122). In some embodiments, the tubes 600 may be located at least partially within the Faraday shield slit 210, such as at least partially within a space vertically defined between the top annular portion 202 and bottom annular portion 204 of the Faraday shield 128.

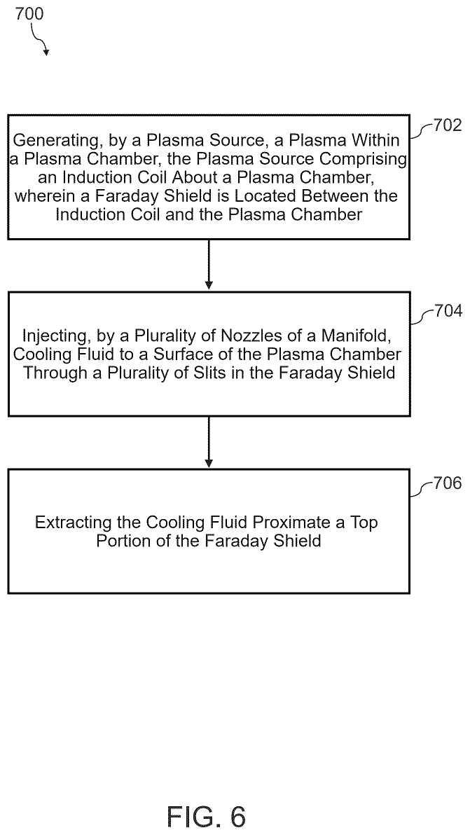

FIG. 6 depicts a flow diagram of an example method 700 for cooling a plasma source according to example embodiments of the present disclosure. Method 700 can be implemented by a plasma source cooling system, such as the plasma source cooling system described herein. Further, method 700 can be implemented in any suitable plasma processing apparatus, such as plasma processing apparatus 100 described in FIG. 1 or FIG. 4. FIG. 6 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At 702, the method 700 can include generating, by a plasma source, a plasma within a plasma chamber, the plasma source comprising an induction coil about a plasma chamber, wherein a Faraday shield is located between the induction coil and the plasma chamber.

At 704, the method 700 can include injecting, by a plurality of nozzles of a manifold, cooling fluid to a surface of the plasma chamber through a plurality of slits in the Faraday shield. In some embodiments, step 704 may include supplying the cooling fluid to the plasma chamber at a position defined by the induction coil.

In some embodiments, the method 700 may further include a step 706, which includes extracting the cooling fluid proximate a top portion of the Faraday shield. In some embodiments, the cooling fluid may be extracted proximate the top portion of the Faraday shield by one or more fans.

One example embodiment of the present disclosure is directed to a plasma processing apparatus including a plasma source. The plasma source includes an induction coil about a dielectric tube. The plasma processing apparatus further includes a Faraday shield located between the induction coil and the dielectric tube. The Faraday shield includes a plurality of Faraday shield slits. The plasma processing apparatus further includes a plasma source cooling system including a manifold. The manifold includes a plurality of nozzles, each nozzle configured to supply cooling fluid onto a surface of the dielectric tube through one of the Faraday shield slits of the plurality of Faraday shield slits.

In some embodiments, the manifold is a ring-shaped manifold.

In some embodiments, the cooling fluid is a cooling gas.

In some embodiments, the cooling gas is air.

In some embodiments, each nozzle of the plurality of nozzles of the manifold is configured to supply cooling fluid onto the surface of the dielectric tube at a position defined by the induction coil.

In some embodiments, the plasma source cooling system further includes a blower configured to supply cooling fluid to the manifold.

In some embodiments, the Faraday shield is grounded.

In some embodiments, the plasma source cooling system further include a plurality of tubes located at least partially within the plurality of Faraday shield slits, the plurality of tubes coupled to the plurality of nozzles and configured to direct cooling gas through the plurality of Faraday shield slits to cool the surface of the dielectric tube.

In some embodiments, each of the plurality of nozzles of the manifold are configured to inject the cooling gas to the surface of the dielectric tube at a speed of about 8 m/s.

In some embodiments, each nozzle of the plurality of nozzles of the manifold have an opening diameter in a range of about 3 mm to about 12 mm.

Aspects of the present disclosure are also directed to a plasma source cooling system including a plasma chamber cage configured to house the plasma source and a Faraday shield, the Faraday shield located between an induction coil and a dielectric tube of the plasma source, the Faraday shield comprising a plurality of Faraday shield slits. The plasma source cooling system further includes a manifold located within a lower portion of the plasma chamber cage, the manifold comprising a plurality of nozzles, each nozzle configured to supply cooling fluid to the plasma source through one of the Faraday shield slits of the plurality of Faraday shield slits.

In some embodiments, the manifold is a ring-shaped manifold.

In some embodiments, the cooling fluid is a cooling gas.

In some embodiments, each nozzle of the plurality of nozzles is configured to supply cooling fluid onto a surface of the dielectric tube at a position defined by the induction coil.

In some embodiments, the plasma source cooling system further comprises a blower configured to supply cooling fluid to the manifold.

In some embodiments, the plasma source cooling system further includes a plurality of fans located on an upper portion of the plasma chamber cage, the plurality of fans configured to extract the cooling fluid from the plasma chamber cage.

In some embodiments, the plurality of fans include a first plurality of fans located on an external surface of a first side wall of the plasma chamber cage; and a second plurality of fans located on an external surface of a second side wall of the plasma chamber cage; wherein the first side wall is located opposite the second side wall.

Aspects of the present disclosure are also directed to a method for cooling a plasma source. The method includes generating, by a plasma source, a plasma within a plasma chamber, the plasma source comprising an induction coil about a plasma chamber, wherein a Faraday shield is located between the induction coil and the plasma chamber. The method also includes injecting, by a plurality of nozzles of a manifold, cooling fluid to a surface of the plasma chamber through a plurality of slits in the Faraday shield.

In some embodiments, injecting, by a plurality of nozzles of a manifold, cooling fluid to the surface of the plasma chamber through a plurality of slits in the Faraday shield includes supplying the cooling fluid to the plasma chamber at a position defined by the induction coil.

In some embodiments, the method for cooling a plasma source further includes extracting the cooling fluid proximate a top portion of the Faraday shield.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus, the apparatus comprising:
a plasma source comprising an induction coil about a dielectric tube;
a Faraday shield located between the induction coil and the dielectric tube, the Faraday shield comprising a plurality of Faraday shield slits; and
a plasma source cooling system, the plasma source cooling system comprising:
a manifold comprising a plurality of nozzles, each nozzle configured to supply cooling fluid onto a surface of the dielectric tube through one of the Faraday shield slits of the plurality of Faraday shield slits.

2. The apparatus of claim 1, wherein the manifold is a ring-shaped manifold.

3. The apparatus of claim 1, wherein the cooling fluid is a cooling gas.

4. The apparatus of claim 3, wherein the cooling gas is air.

5. The apparatus of claim 1, wherein each nozzle of the plurality of nozzles is configured to supply cooling fluid onto the surface of the dielectric tube at a position defined by the induction coil.

6. The apparatus of claim 1, wherein the plasma source cooling system further comprises a blower configured to supply cooling fluid to the manifold.

7. The apparatus of claim 1, wherein the Faraday shield is grounded.

8. The apparatus of claim 1, wherein the plasma source cooling system further comprises:
a plurality of tubes located at least partially within the plurality of Faraday shield slits, the plurality of tubes coupled to the plurality of nozzles and configured to direct cooling gas through the plurality of Faraday shield slits to cool the surface of the dielectric tube.

9. The apparatus of claim 3, wherein each of the plurality of nozzles of the manifold are configured to inject the cooling gas to the surface of the dielectric tube at a speed of about 8 m/s.

10. The apparatus of claim 1, wherein each nozzle of the plurality of nozzles of the manifold have an opening diameter in a range of about 3 mm to about 12 mm.

11. A plasma source cooling system, the system comprising:
a plasma chamber cage configured to house the plasma source and a Faraday shield, the Faraday shield located between an induction coil and a dielectric tube of the plasma source, the Faraday shield comprising a plurality of Faraday shield slits; and
a manifold located within a lower portion of the plasma chamber cage, the manifold comprising a plurality of nozzles, each nozzle configured to supply cooling fluid to the plasma source through one of the Faraday shield slits of the plurality of Faraday shield slits.

12. The system of claim 11, wherein the manifold is a ring-shaped manifold.

13. The system of claim 11, wherein the cooling fluid is a cooling gas.

14. The system of claim 11, wherein each nozzle of the plurality of nozzles is configured to supply cooling fluid onto a surface of the dielectric tube at a position defined by the induction coil.

15. The system of claim 11, wherein the plasma source cooling system further comprises a blower configured to supply cooling fluid to the manifold.

16. The system of claim 11 further comprising:
a plurality of fans located on an upper portion of the plasma chamber cage, the plurality of fans configured to extract the cooling fluid from the plasma chamber cage.

17. The system of claim 16, wherein the plurality of fans comprises:
a first plurality of fans located on an external surface of a first side wall of the plasma chamber cage; and
a second plurality of fans located on an external surface of a second side wall of the plasma chamber cage;
wherein the first side wall is located opposite the second side wall.

18. A method for cooling a plasma source, the method comprising:
generating, by a plasma source, a plasma within a plasma chamber, the plasma source comprising an induction coil about a plasma chamber, wherein a Faraday shield is located between the induction coil and the plasma chamber; and
injecting, by a plurality of nozzles of a manifold, cooling fluid to a surface of the plasma chamber through a plurality of slits in the Faraday shield.

19. The method of claim 18, wherein injecting, by a plurality of nozzles of a manifold, cooling fluid to the surface of the plasma chamber through a plurality of slits in the Faraday shield comprises supplying the cooling fluid to the plasma chamber at a position defined by the induction coil.

20. The method of claim 18, the method further comprising:
extracting the cooling fluid proximate a top portion of the Faraday shield.
